(19) United States
(12) Patent Application Publication
(10) Pub. No.: US 2012/0060913 A1
(43) Pub. Date: Mar. 15, 2012

(54) WHISPERING GALLERY SOLAR CELLS

(75) Inventors: Jonathan Grandidier, Pasadena, CA (US); Jeremy Munday, North Bethesda, MD (US); Dennis Callahan, Los Angeles, CA (US); Harry A. Atwater, South Pasadena, CA (US)

(73) Assignee: CALIFORNIA INSTITUTE OF TECHNOLOGY, Pasadena, CA (US)

(21) Appl. No.: 13/231,111

(22) Filed: Sep. 13, 2011

Related U.S. Application Data
(60) Provisional application No. 61/382,422, filed on Sep. 13, 2010.
(60) Provisional application No. 61/498,282, filed on Jun. 17, 2011.

(51) Int. Cl. H01L 31/0232; H01L 31/0216; B82Y 99/00

(52) U.S. Cl. 136/256; 977/948; 977/773

(57) ABSTRACT

This disclosure relates to structures for the conversion of light into energy. More specifically, the disclosure describes devices for conversion of light to electricity using photovoltaic cells layered with a nanostructure that resonates and undergoes Whispering Gallery Mode.

### CROSS REFERENCE TO RELATED APPLICATIONS

This application claims priority under 35 U.S.C. §119 from Provisional Application Ser. Nos. 61/382,422, filed Sep. 13, 2010 and 61/498,282, filed Jun. 17, 2011, the disclosures of which are incorporated herein by reference.

### STATEMENT REGARDING FEDERALLY SPONSORED RESEARCH

This invention was made with government support under grant DE-SC0001293 awarded by the Department of Energy. The government has certain rights in the invention.

### TECHNICAL FIELD

This disclosure relates to structures for the conversion of light into energy. More specifically, the disclosure describes devices for conversion of light to electricity using solar cells layered with nanostructure that undergoes whispering gallery light capture.

### BACKGROUND

Obtaining light energy as an energy substitute for coal and oil is important.

### SUMMARY

The disclosure provides an electrical energy generating device, comprising a photovoltaic cell and a plurality of nanostructures layered adjacent to a surface of the photovoltaic cell, wherein the nanostructures undergo resonance when contacted with incident light and wherein light passes through the nanostructures before entering the photovoltaic cell. In one embodiment, the surface is a side of an anti-reflective coating included on the photovoltaic cell and the nanoparticles each physically and directly contacts the surface. In one embodiment, the anti-reflective coating is electrically conductive. In one embodiment, the nanostructures are each constructed of a dielectric material. In one embodiment, the nanostructures each include SiO₂. In one embodiment, each nanostructure is a nanosphere. In one embodiment, each nanosphere has a diameter and the diameter of each nanosphere is the same. In one embodiment, each nanosphere has a diameter in a range of 1 nm to 2500 nm. In another embodiment, each nanosphere has a diameter in a range of 100 nm to 900 nm. In yet another embodiment, each nanosphere has a diameter and the diameters are heterogeneous. In one embodiment, the nanoparticles are arranged in a one nanostructure thick monolayer. In one embodiment, the nanostructures are configured such that whispering gallery modes of light having a wavelength in a range from about UV to long infrared resonate within the nanostructure. In one embodiment, the wavelength of light the resonates within the nanostructure is from about 380 nm to 780 nm. The nanostructures can be optimized in size to resonate at a desired wavelength depending upon the semiconductive absorbing material. In one embodiment, the nanostructures are configured such that whispering gallery modes of light at a 650 nm wavelength resonate within the nanostructures. In any of the foregoing embodiments, the nanostructures can be nanospheres. In one embodiment, the nanostructures are arranged in a repeating pattern. In one embodiment, the nanostructures are arranged in a periodic pattern. In one embodiment, the nanostructures are spaced from one another by about 10-200 nm. In one embodiment, the nanostructures each physically and directly contacted with each of the nearest nanostructures. In one embodiment, the nanostructures are arranged in a two dimensional lattice. In one embodiment, the nanostructures are arranged in a close packed hexagonal structure. In one embodiment, the photovoltaic cell comprises a light absorbing semiconductive material. In one embodiment, the light-absorbing semiconductive material includes at least one dopant selected from a group consisting of a p-type dopant and an n-type dopant. In another embodiment, the semiconductive material is selected from a group consisting of amorphous silicon, germanium, indium gallium phosphide, and gallium III arsenide. In one embodiment, the photovoltaic cell comprises a layer of a light-absorbing semiconductive material and the layer has a thickness in a range of 10 to 1000 nm.

The disclosure provides an electrical energy generating device, comprising a solar cell having a surface through which light enters and a light-absorbing medium that absorbs the light that enters the solar cell, the solar cell being configured to convert the absorbed light to electrical energy; and nanostructures immobilized relative to the surface such that the light passes through the nanostructures before entering the solar cell, each nanoparticle being a nanosphere and each nanosphere having a diameter in a range of 1 nm to 2500 nm, the nanostructures being arranged in a one nanostructures thick monolayer such that the nanostructures are in a lattice configuration, and the nanostructures being configured such that whispering gallery modes of light having a wavelength in a range of 380 nm to 780 nm resonate within the nanoparticles.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1A-C show schematics of a dielectric nanosphere solar cell of the disclosure. (A-B) shows a schematic of a solar cell. (C) shows a diagram of guided modes and propagation modes.

FIG. 2 shows a current density calculated in the amorphous silicon layer with (solid line) and without (dashed line) the presence of a nanosphere.

FIG. 3 shows a cross section of a silica nanosphere on an amorphous silicon layer with an AZO and silver back contact layer.

FIG. 4 shows an integrated electric field and absorption for normal incidence of a cross section at the center of the sphere at the resonant frequency corresponding to λ=665 nm.

FIG. 5 shows an electric field intensity cross section at the middle of a sphere in the (x,z)-plane at 665 nm.

FIG. 6 shows the direction of the electric field of the incident plane wave of FIG. 5.

FIG. 7 shows an enlargement of the direction of the electric field of the incident plane wave shown in FIG. 6.

FIG. 8 shows an electric field intensity cross section at the middle of a sphere in the (x,z)-plane at 747 nm.

FIG. 9 shows the direction of the electric field of the incident plane wave of FIG. 8.

FIG. 10 shows an enlargement of the direction of the electric field of the incident plane wave shown in FIG. 9.

FIG. 11 shows a schematic of the flat case model with an angle and spectral current density.

FIG. 12 shows a graph of a TE polarization.

FIG. 13 shows a graph of a TM polarization.

FIG. 14 shows a schematic of the case with nanospheres on top and spectral current density.

FIG. 15 shows a graph based on FIG. 14 with TE polarization.

FIG. 16 shows a graph based on FIG. 14 with TM polarization.

FIG. 17 shows a schematic of the periodic arrangement of the nanospheres with a large lattice constant. The rectangle indicates the unit cell used for numerical simulations.

FIG. 18 shows a current density for three different sphere spacings when an efficient coupling between the spheres exists.

FIG. 19 shows a current density for a flat cell and with a relatively large distance between the spheres (λ=1000 nm).

FIG. 20 shows the ratio between the spectral current density of a solar cell with hexagonally close-packed spheres over the spectral current density of a solar cell without spheres.

FIG. 21 shows current density of a flat GaAs solar cell with back reflector and double anti-reflection coating as a function of the GaAs thickness.

FIG. 22 shows an analytically calculated generated current related to the light absorbed in different GaAs layer thicknesses. The spectral range is weighted by the solar spectrum and compared with the Am1.5 solar spectrum.

FIG. 23A-E. (a) Cross section of a silica nanosphere on a flat GaAs solar cell with back reflector and double layer anti-reflection coating. (b) Spectral current density of a 100 nm thick GaAs flat cell and a cell with a hexagonally close-packed monolayer array of 700 nm diameter dielectric nanospheres. Each peak labeled (c), (d) and (e) correspond to different whispering gallery mode orders where the electric field intensity for a cross section at the middle of a sphere at different wavelengths for the labeled peaks are shown. The E field of the initial plane wave is oriented in the (x,z) plane. The black circles show the contour of the sphere.

FIG. 24A-F show the ratio between the spectral current density of a solar cell with hexagonally close packed spheres over the spectral current density of a solar cell without spheres for a (a) 100 nm, (b) 500 nm and (c) 1000 nm thick GaAs solar cell. (d,e,f) Current density of a solar cell as a function of the sphere diameter above it. The current of the equivalent flat cell is also represented. On (d) and (e) is represented for the highest value obtained with sphere what thickness of an equivalent flat GaAs solar cell would be. On (f), the red dots show the value for the written spacing between the spheres.

### DETAILED DESCRIPTION

As used herein and in the appended claims, the singular forms “a,” “and,” and “the” include plural referents unless the context clearly dictates otherwise. Thus, for example, reference to “a substrate” includes a plurality of such substrates and reference to “the cell” includes reference to one or more cells and equivalents thereof.

Unless defined otherwise, all technical and scientific terms used herein have the same meaning as commonly understood to one of ordinary skill in the art to which this disclosure belongs. Although any methods and reagents similar or equivalent to those described herein can be used in the practice of the disclosed methods and compositions, the exemplary methods and materials are now described.

All publications mentioned herein are incorporated herein by reference in full for the purpose of describing and disclosing the methodologies, which are described in the publications, which might be used in connection with the description herein. The publications discussed above and throughout the text are provided solely for their disclosure prior to the filing date of the present application. Nothing herein is to be construed as an admission that the inventors are not entitled to antedate such disclosure by virtue of prior disclosure.

Also, the use of “or” means “and/or” unless stated otherwise. Similarly, “comprise,” “comprises,” “comprising” “include,” “includes,” and “including” are interchangeable and not intended to be limiting.

It is to be further understood that where descriptions of various embodiments use the term “comprising,” those skilled in the art would understand that in some specific instances, an embodiment can be alternatively described using language “consisting essentially of” or “consisting of:”

Electromagnetic Radiation to Electric Energy Conversion Device (EREECD) is a device that reacts with electromagnetic (optical) radiation to produce electrical energy. Optoelectronic Energy Device (OED) refers to a device that reacts with optical radiation to produce electrical energy with an electronic device. As used herein, the term “ultraviolet range” refers to a range of wavelengths from about 5 nm to about 400 nm. As used herein, the term “visible range” refers to a range of wavelengths from about 400 nm to about 700 nm. As used herein, the term “infrared range” refers to a range of wavelengths from about 700 nm to about 2 mm. The infrared range includes the “near infrared range,” which refers to a range of wavelengths from about 700 nm to about 5 μm, the “middle infrared range,” which refers to a range of wavelengths from about 5 μm to about 30 μm, and the “far infrared range,” which refers to a range of wavelengths from about 30 μm to about 2 mm.

A photovoltaic cell is an electrical device comprising a semiconductor that converts light or other radiant energy, in the range from ultraviolet to infrared radiation, incident on its surface into electrical energy in the form of power/voltage/current and which has two electrodes, usually a diode with a top electrode and a bottom electrode with opposite electrical polarities. The photovoltaic cell produces direct current which flows through the electrodes. As employed herein, the term photovoltaic cell is generic to cells which convert radiant energy into electrical energy. A solar cell is a photocell that converts light including solar radiation incident on its surface into electrical energy.

A photovoltaic (“PV”) cell may be connected in parallel, in series, or a combination thereof with other such cells. A common PV cell is a p-n junction device based on crystalline silicon. Other types of PV cells can be based on semiconductive materials, such as, but not limited to, amorphous silicon, polycrystalline silicon, germanium, organic materials, and Group III-V semiconductor materials, such as gallium arsenide (GaAs).

During operation of a photovoltaic cell, incident solar or light radiation penetrates below a surface of the PV cell and is absorbed. The depth at which the solar radiation penetrates depends upon an absorption coefficient of the cell. In the case of a PV cell based on silicon, an absorption coefficient of silicon varies with wavelength of solar radiation. At a particular depth within the PV cell, absorption of solar radiation produces charge carriers in the form of electron-hole pairs. Electrons flow through one electrode connected to the cell, while holes exit through another electrode connected to the cell. The effect is a flow of an electric current through the cell driven by incident solar radiation. Inefficiencies exist in current solar cells due to the inability to collect/use and convert the entire incident light.

Also, in accordance with a junction design of a PV cell, charge separation of electron-hole pairs is typically confined to a depletion region, which can be limited to a thickness of about 1 μm. Electron-hole pairs that are produced further than a diffusion or drift length from the depletion region typically do not charge separate and, thus, typically do not contribute to the conversion into electrical energy. The depletion region is typically positioned within the PV cell at a particular depth below a surface of the PV cell. The variation of the absorption coefficient of silicon across an incident solar spectrum can impose a compromise with respect to the depth and other characteristics of the depletion region that reduces the efficiency of the PV cell. For example, while a particular depth of the depletion region can be desirable for solar radiation at one wavelength, the same depth can be undesirable for solar radiation at a shorter wavelength. In particular, since the shorter wavelength solar radiation can penetrate below the surface to a lesser degree, electron-hole pairs that are produced can be too far from the depletion region to contribute to an electric current.

The term “wider band-gap” refers to the difference in band-gaps between a first material and a second material. “Band-gap” or “energy band gap” refers to the characteristic energy profile of a semiconductor that determines its electrical performance, current and voltage output, which is the difference in energy between the valence band maximum and the conduction band minimum.

For thin-film solar cells, light absorption is usually proportional to the film thickness. However, if freely propagating sunlight can be transformed into a guided mode, the optical path length significantly increases and results in enhanced light absorption within the cell.

Thin-film photovoltaics offer the potential for a significant cost reduction compared to traditional, or first generation, photovoltaics usually at the expense of high efficiency. This is achieved mainly by the use of amorphous or polycrystalline optoelectronic materials for the active region of the device, for example, amorphous-Si (a-Si). The resulting carrier collection efficiencies, operating voltages, and fill factors are typically lower than those for single-crystal cells, which reduce the overall cell efficiency. There is thus great interest in using thinner active layers combined with advanced light trapping schemes to minimize these problems and maximize efficiency.

The disclosure provides a dielectric nanostructure layer for light trapping in thin-film solar cells. In one embodiment, the nanostructure comprises wavelength-scale resonant dielectric nanospheres that support whispering gallery modes (WGM) (referred to as “WGM-layer”) to enhance absorption and photocurrent. In certain embodiments, the disclosure provide methods and devices for coupling light into smooth untextured thin film solar cells of uniform thickness using periodic arrangements of resonant dielectric nanospheres deposited as a continuous film on top of a thin PV cell. This allows use of materials with high electronic properties. In other embodiments, the textured thin film solar cells can be used.

The WGM-layer comprises micro- or nanostructures (e.g., nanospheres) that generate a whispering gallery mode that can be coupled into particular modes of the solar cell to enhance the cell's efficiency. The data provided herein demonstrate this enhancement using full-field finite difference time-domain (FDTD) simulations of a nanosphere array above a typical thin-film amorphous silicon (a-Si) solar cell structure; however, it will be recognized that other common semiconductive material used in solar cells may be substituted for a-Si. The in-coupling element in this design is advantageous over other schemes as it is composed of a loss-less material, and its spherical or substantially spherical symmetry naturally accepts large angles of incidence. In addition, the array can be fabricated using simple, well-developed methods of self-assembly and is easily scalable without the need for lithography or patterning. The design provided herein can be extended to many other thin-film solar cell materials to enhance photocurrent and angular sensitivity.

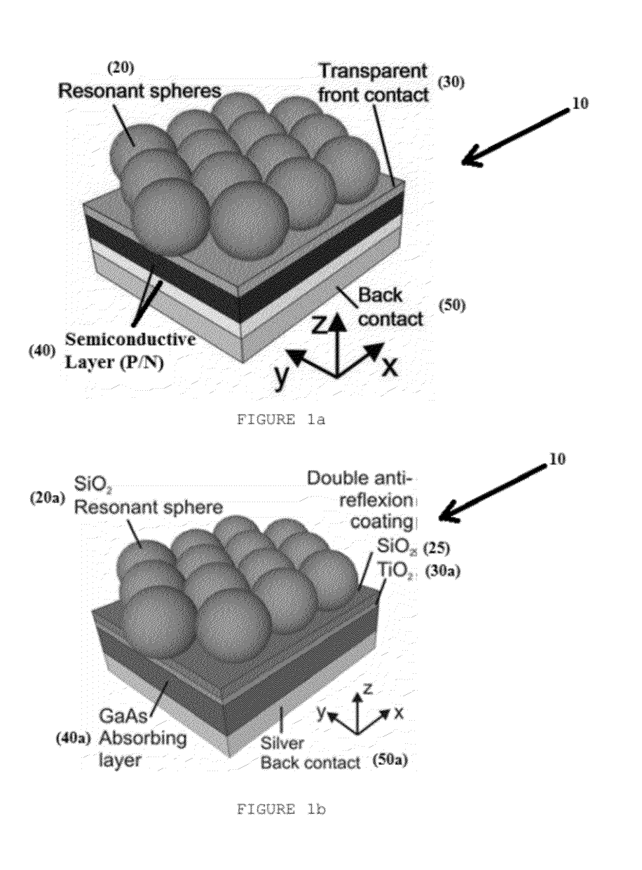

FIG. 1a depicts a general solar device 10 of the disclosure. The solar device comprises a photovoltaic cell comprising an front/top electrode contact 30/30a, electrically coupled to a semiconductive (“absorber”) layer 40/40a (note for simplicity the P-type and N-type layers are depicted in FIG. 1a and are generally referred to as the semiconductive layer), which in turn is electrically coupled to a back/bottom electrode 50/50a. Typically either the front/top electrode 30/30a and/or back/bottom electrode 40/40a comprise a conductive transparent material such as, for example, TiO₂. Electrodes 30/30a/40/40a conduct electrons and accordingly comprise a metal or other conductive material (e.g., Au, Ag, Cu and the like). In addition, anti-reflective coatings may be disposed on the cell (e.g., see FIG. 1b at 25).

The semiconductive layer 40/40a can comprise any suitable material used in photovoltaic cells that can comprise a p-type or n-type semiconductive material. For example, polystyrene spheres have been used in the methods and compositions of the disclosure.

As discussed herein, embodiments of the disclosure may be used in photocell applications. As such, the semiconductor structures typically comprise semiconductor material having properties for effective solar energy absorption and conversion of that energy to electricity. Such material may comprise crystalline silicon, either monocrystalline silicon or polycrystalline silicon, and doped or undoped. The semiconductor material may also be amorphous silicon, micromorphous silicon, protocrystalline silicon or nanocrystalline silicon. The semiconductor material may also be cadmium telluride; copper-indium selenide, copper indium gallium selenide gallium arsenide, gallium arsenide phosphide, cadmium selenide, indium phosphide, or a-Si:H alloy or combinations of other elements from groups I, III and VI in the periodic table as well as transition metals; or other inorganic elements or combinations of elements known in the art for having desirable solar energy conversion properties.

The term “semiconductor” or “semiconductive material” is generally used to refer to elements, structures, or devices, etc. comprising materials that have semiconductive properties, unless otherwise indicated. Such materials include, but are not limited to: elements from Group IV of the periodic table; materials including elements from Group IV of the period table; materials including elements from Group III and Group V of the periodic table; materials including elements from Group II and Group VI of the periodic table; materials including elements from Group I and Group VII of the periodic table; materials including elements from Group IV and Group VI of the periodic table; materials including elements from Group V and Group VI of the periodic table; and materials including elements from Group II and Group V of the periodic table. Other materials with semiconductive properties may include: layered semiconductors; metallic alloys; miscellaneous oxides; some organic materials, and some magnetic materials. A semiconductor structure may comprise either doped or undoped material.

N/P junction refers to a connection between a p-type semiconductor and an n-type semiconductor which produces a diode. Depletion region refers to the transition region between an n-type region and a p-type region of an N/P junction where a high electric field exists.

The term “GaNPAs layer” refers to a nanometer to several micrometer thick epitaxial layer of NaNₓP_{1-x-y}As_{y} (e.g., a direct-gap III-V alloy). As used herein, the term “III-V materials” or “III-V alloys” refers to the compounds formed by chemical elements from Group III and Group V from the periodic table of elements and can include binary, ternary, quaternary compounds and compounds with higher number of elements from Groups III and V. Similarly, other alloys such as AlGaP, for example, could have any ratio of Al:Ga, and the like.

As used herein, the term “III-P materials” or “III-P alloys” includes, but is not limiting to, AlP, GaP, InP, GaInP, AlGaP, AINP, GaNP, InNP, AlGaInP, AIPN, GaPN, InPN, AlGaNP, GaInNP, AlInNP and AlGaInNP.

As used herein, the term “II-VI material” includes, but is not limited to, CdSe, CdS, CdTe, ZnO, ZnSe, ZnS, ZnTe, CdZnTe, HgCdTe, HgZnTe, and HgZnSe, or alloys thereof.

FIG. 1a-b also depict a WGM-layer comprising a plurality of nanospheres 20/20a that undergo resonance upon contact with light. The resonance generates a whispering gallery mode that is optically coupled between adjacent nanospheres and with the semiconductive layer 40/40a. The nanospheres 40/40a can comprise any dielectric material including, but not limited to SiO₂. Further, by “optically coupled” is meant that light radiation can be transmitted to the semiconductive material. The nanospheres need not be in direct contact with the semiconductive substrates. For example, in FIGS. 1a and b, the nanospheres 20/20a are separated from the semiconductive material by a transparent front contact 30 or a combination of a transparent contact 30a and an antireflective coating 25.

Generally as used herein, “nanostructure” or “nanoparticle” refers to nanospheres or other nanostructures suitable for optical resonance. As used herein, “nanoparticle” refers to a particle with a diameter in the nanometers (nm). As used herein, “nanosphere” refers to a substantially hollow particle with a diameter in the nanometers. The nanosphere need not be perfectly spherical and may be oblong, substantially cuboidal and the like. The nanosphere is typically made of any dielectric material such as, but not limited to, SiO₂.

As used herein, the term “nanometer range” or “nm range” refers to a range of dimensions from about 1 nm to about 1 μm. The nm range includes the “lower nm range,” which refers to a range of dimensions from about 1 nm to about 10 nm, the “middle μm range,” which refers to a range of dimensions from about 10 nm to about 100 nm, and the “upper nm range,” which refers to a range of dimensions from about 100 nm to about 1 μm.

As used herein, the term “micrometer range” or “μm range” refers to a range of dimensions from about 1 μm to about 1 mm. The μm range includes the “lower μm range,” which refers to a range of dimensions from about 1 μm to about 10 μm, the “middle μrange,” which refers to a range of dimensions from about 10 μm to about 100 μm, and the “upper μm range,” which refers to a range of dimensions from about 100 μm to about 1 mm.

As used herein, the term “size” refers to a characteristic dimension of an object. In the case of an object that is spherical, a size of the object can refer to a diameter of the object. In the case of an object that is non-spherical, a size of the object can refer to an average of various orthogonal dimensions of the object. Thus, for example, a size of an object that is a spheroidal can refer to an average of a major axis and a minor axis of the object. When referring to a set of objects as having a particular size, it is contemplated that the objects can have a distribution of sizes around that size. Thus, as used herein, a size of a set of objects can refer to a typical size of a distribution of sizes, such as an average size, a median size, or a peak size.

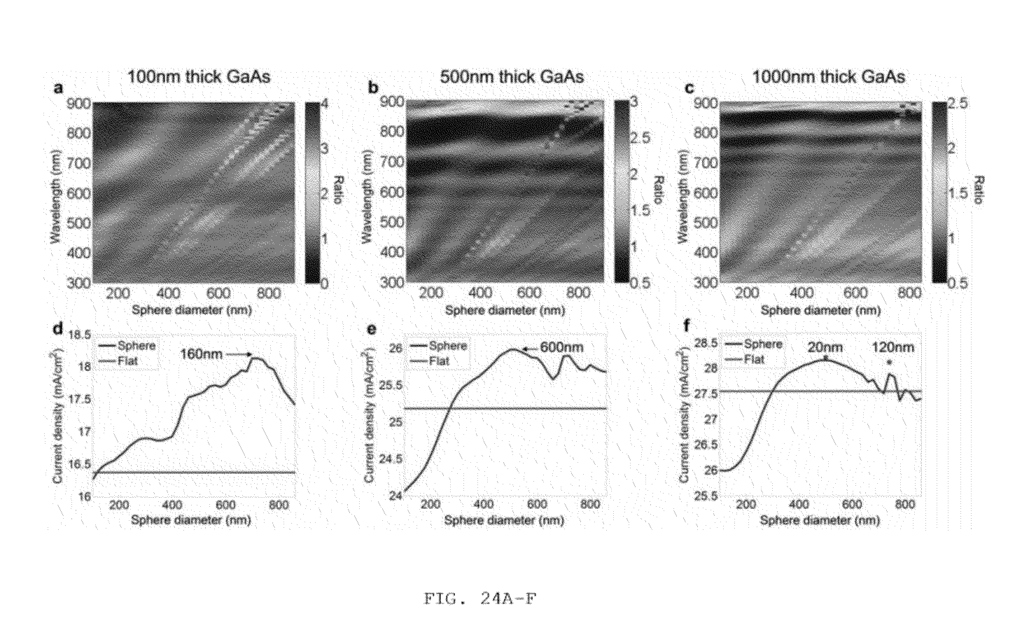

FIGS. 3 and 23A further show the layers of a solar device of the disclosure. For example, FIG. 3 shows nanosphere 20 comprising SiO₂ in contact with a transparent conductive electrode 30a, which is in contact with a semiconductive material comprising amorphous Si 40, which is in-turn in contact with a bottom/back electrode and reflective surface/metal 50a.

During use, incident light contacts the nanosphere 20, the light is reflected and resonance within the nanosphere. The resonating light “leaks” to adjacent spheres or in the direction of the semiconductive material 40. Incident light can also directly contact the semiconductive material 40. Within the semiconductive material electron-hole pairs are formed and a current is then generated as is well understood in the photovoltaic field. The resonance and reflective internal dimension of the spheres provides the ability to “capture” light from various incident angles compared to a purely flat semiconductive photovoltaic device. Further, because the nanospheres resonance there is a further transmission of resonance light towards the semiconductive material. In this manner efficiency of incident light contacting the semiconductive substrate is improved compared to a first or second generation photovoltaic cell lacking a WGM-layer.

As used herein, the terms “reflection,” “reflect,” and “reflective” refer to a bending or a deflection of light, and the term “reflector” refers to an element that causes, induces, or is otherwise involved in such bending or deflection. A bending or a deflection of light can be substantially in a single direction, such as in the case of specular reflection, or can be in multiple directions, such as in the case of diffuse reflection or scattering. In general, light incident upon a material and light reflected from the material can have wavelengths that are the same or different.

Wavelength-scale dielectric nanospheres are photonic elements because they can diffractively couple light from free space and also support confined resonant modes. Moreover, the periodic arrangement of nanospheres can lead to coupling between the spheres, resulting in mode splitting and rich band structure. The coupling originates from whispering gallery modes (WGM) inside the spheres. When resonant dielectric nanospheres are in proximity to a high-index photovoltaic absorber layer, incident light can be coupled into the high-index material and can increase light absorption. Another important benefit of this structure for photovoltaic application is its spherical geometry that naturally accepts light from large angles of incidence.

Guided optical modes involve propagation of emitted radiation along a longitudinal direction (see, e.g., FIG. 1c). Guided optical modes can also include whispering-gallery optical modes, which involves propagation of incident solar radiation or emitted radiation in orbital paths along a circumference of the nanosphere layer (e.g., internally reflected radiation). The whispering-gallery optical modes can yield improvements in efficiency by trapping radiation within the nanosphere with little or no losses, while allowing optical coupling of the trapped radiation to guided optical modes propagating along the longitudinal direction.

The internally reflected radiation produces an evanescent wave on the other side of the boundary. Essentially a little of the radiation “leaks out”, extending a very small distance out of the medium (e.g., nanosphere) into the associated boundary. Accordingly, if you bring a second identical medium (e.g., another nanosphere) that also supports total internal reflection, and you position it so close that the two regions of evanescent waves overlap, then the radiation couples from one into the other. This is referred to as “optical coupling.” Further, if the optically coupled nanospheres are coupled to a semiconductive photo absorbing layer (i.e., a photovoltaic material/solar cell), the optical energy of the nanospheres can be optically coupled to the photovoltaic cell.

For example, the disclosure demonstrates that most of incident light energy is present inside a dielectric sphere and the field exponentially decays outside of the sphere. This corresponds to an evanescent wave described by the Hankel function shape of the mode. This behavior has advantages for solar applications. Because most of the energy is stored inside the sphere, when it is above a higher index material, it will tend to naturally “leak” into it. Additionally, when two dielectric spheres are close enough, they have the ability to couple to each other. When several sphere modes couple together due to their proximity, it can lead to waveguide formation. Additionally, when the spheres are hexagonally close packed, they can be excited by diffractive coupling and can all couple with each other.

Methods of making photovoltaic cells are known in the art including first generation, second generation and others. The order of reflective, nonreflective, conductive electrodes and semiconductor and various materials used to optimize the photovoltaic cell lacking a WGM-layer are known in the art. The WGM-layer-photovoltaic cell of the disclosure provides distinct and important advances in efficiencies of such photovoltaic cells by, for example, improving the ability to collect light at various incident levels and to generate a Whispering gallery mode effect.

The WGM-layer may be made of any number of different dielectric materials so long as they have a Whispering Gallery Mode effect. Typically the geometry of such materials will be substantially spherical and in certain embodiments spherical. The dimensions of the nanostructures or nanospheres are about 100 nm to 900 nm in diameter, typically about 200 nm to about 800 nm in diameter and may be any of 200, 300, 400, 500, 600, 700, 800 or 900 nm in diameter. Furthermore, the individuals nanospheres may be in direct contact or spaced apart by 10, 20, 30, 40, 50, 60, 70, 80, 90, 100, 110, 120 nm or more. The diameter and spacing of the nanostructures forming the WGM-layer will be determined empirically based upon the composition of the photovoltaic material and the thickness of the photovoltaic device layers. The WGM-layer may comprise a homogenous size of nanostructures or a heterogeneous mixture of different sizes of nanostructures. Nanostructures that can be used in the WGM-layer (e.g., the lossless dielectric layer) can be purchased from a number of commercial suppliers (e.g., Polyscience, Invitrogen, Angstromspheres and Bangs Laboratories).

The WGM-layer-photovoltaic device can be fabricated using standard methods for generating a photovoltaic material. Based on the use of methods such as immersion, casting, spraying, printing or rolling, it is readily possible to coat a photovoltaic cells with an WGM-layer for mass production. The nanostructures may be layered as a monolayer or multilayer on the photovoltaic material using any number of different methods including spraying and Langmuir-Blodgett methods (see, e.g., Bardosova et al., Adv. Mater. 22:3104-3124, 2010).

The following examples are intended to illustrate but not limit the disclosure. While they are typical of those that might be used, other procedures known to those skilled in the art may alternatively be used.

### EXAMPLES

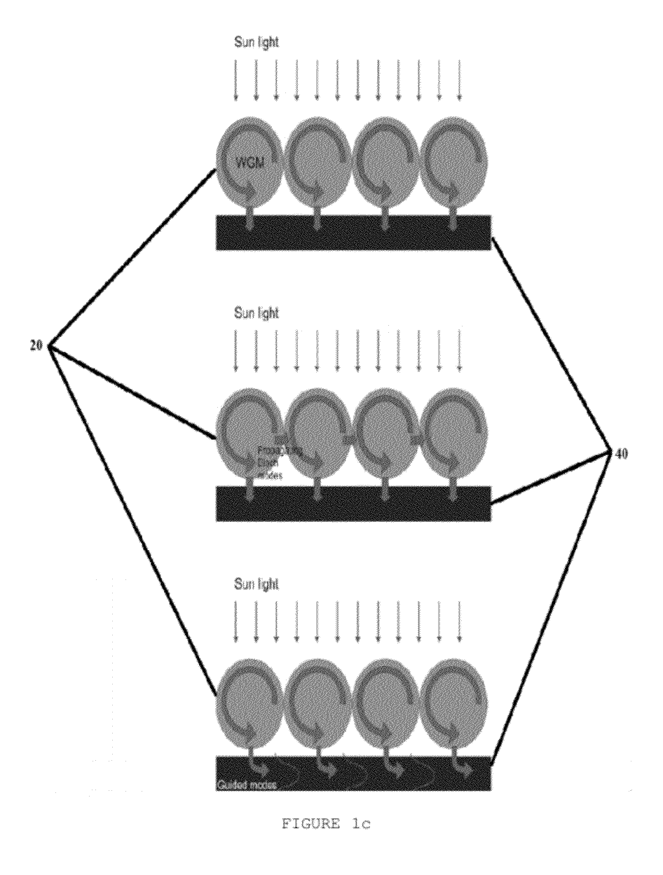

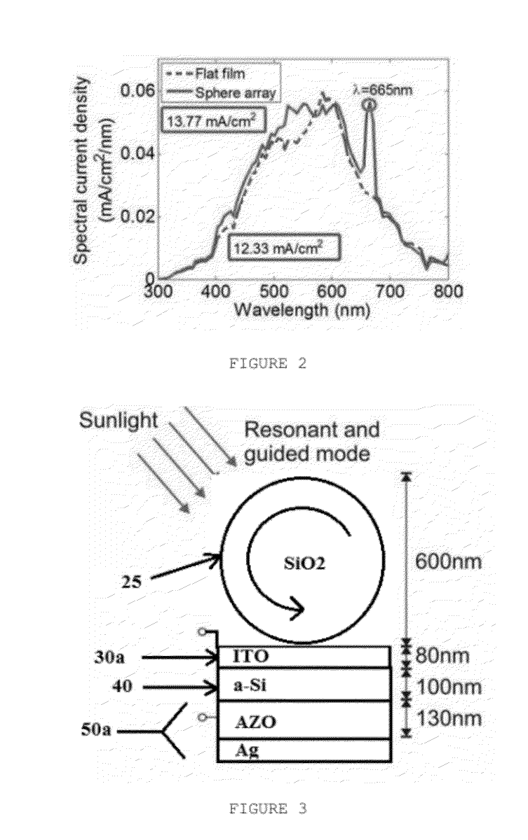

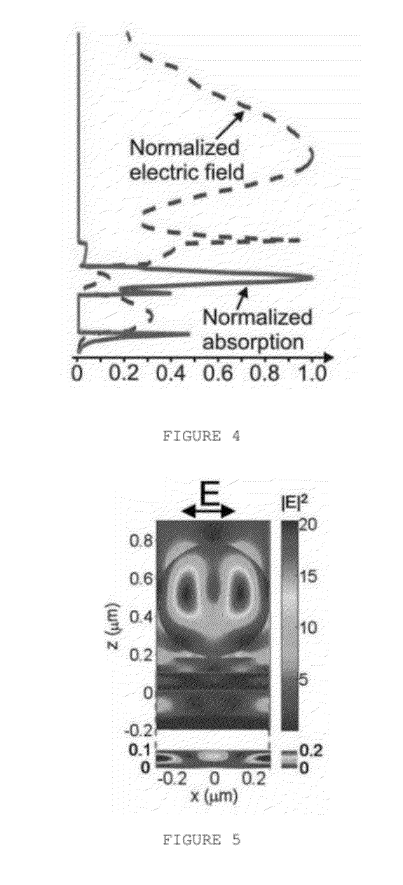

FIG. 1 depicts a solar cell where close packed dielectric resonant nanospheres stand atop a typical a-Si solar cell structure. A cross section is represented in FIG. 2. A silver back contact and, in order to avoid diffusion between the silver layer and the a-Si layer, a 130-nm aluminium-doped zinc oxide (AZO) layer was placed between the silver and the a-Si layer. An 80-nm indium tin oxide (ITO) layer is used as a transparent conducting front contact and also acts as an antireflection coating. 600-nm-diameter silica nanospheres with a refractive index of n=1.46 were directly placed on the ITO as a hexagonally close-packed monolayer array. In order to study the response of the system, 3D full field electromagnetic simulations were performed to determine the expected absorption enhancement compared to a-Si absorbers without a layer of dielectric spheres. A broadband wave pulse with the electric field polarized along the x-axis (see FIG. 1) was injected at normal incidence on the structure, and the fields were monitored at 100 wavelengths equally spaced between λ=300 nm and λ=800 nm. This wavelength range corresponds to the sun's energy spectrum below the bandgap of a-Si. In order to determine how much current can be generated from the structure, the optical generation rate in the silicon was calculated using

$${G}_{opt}^{n} ( ω ) = \int \frac{{ɛ}^{″} ( ω ) {\vert E ( ω ) \vert}_{S}^{2}}{2 ℏ} {Γ}_{solar} ( ω ) d V \qquad ( 1 )$$

where ω is the angular frequency, h⁻ is Planck's constant divided by 2π, ∈″(ω) is the imaginary part of the dielectric function of the silicon, and |E(ω)|²ₛ is the electric field intensity integrated over the simulation volume containing the amorphous silicon. If all electrons generated are collected, this will correspond to the device's current. Γ solar is a factor used to weight each wavelength by the AM1.5 solar spectrum. In FIG. 4, are plotted the normalized integrated electric field and absorption of a cross section at the center of the sphere perpendicular to the incoming plane wave and in the plane of the electric field for the resonant frequency corresponding to λ=665 nm. The absorption is proportional to ∈″(ω)|E(ω)|²ₛ as shown in Equation 1.

To determine the influence of the spheres on the solar cell structure presented in FIG. 1, the spectral current density in the a-Si layer was calculated with and without the presence of 600-nm-diameter nanospheres. The result is presented in FIG. 2. The overall integrated current density corresponding to the energy absorbed in the a-Si in the presence of the nanospheres is J=13.77 mA cm⁻², which corresponds to an enhancement of 12% compared to the case without the sphere array. Over almost the entire wavelength range, the spectral current density is higher with the spheres than without the spheres. Furthermore, discrete enhancements at specific wavelengths exist due to coupling between the spheres and the solar cell. The broadband enhancement can be explained by the spheres acting as a textured antireflection coating. At λ=665 nm, the enhancement is greater than 100%. To explain this increase in the current density, the plot in FIG. 5 of the electric field intensity for a cross section in the middle of a sphere in the (x,z)-plane was generated. Two lobes are observed on each side of the sphere. These are characteristic of WGMs. They have significant field strength within the periodic arrangement of the sphere layer.

The WGMs of the spheres couple with each other due to their proximity, which can lead to waveguide formation. A planar waveguide mode can be formed by a 1D chain of touching spheres and has been termed as a “nanojet” mode; in this case, it is simply extended to two dimensions.

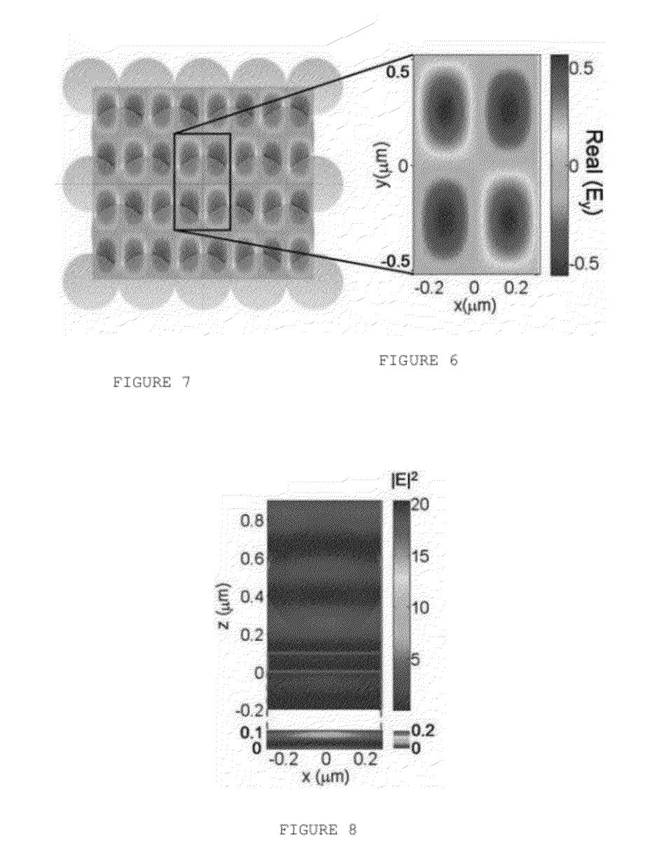

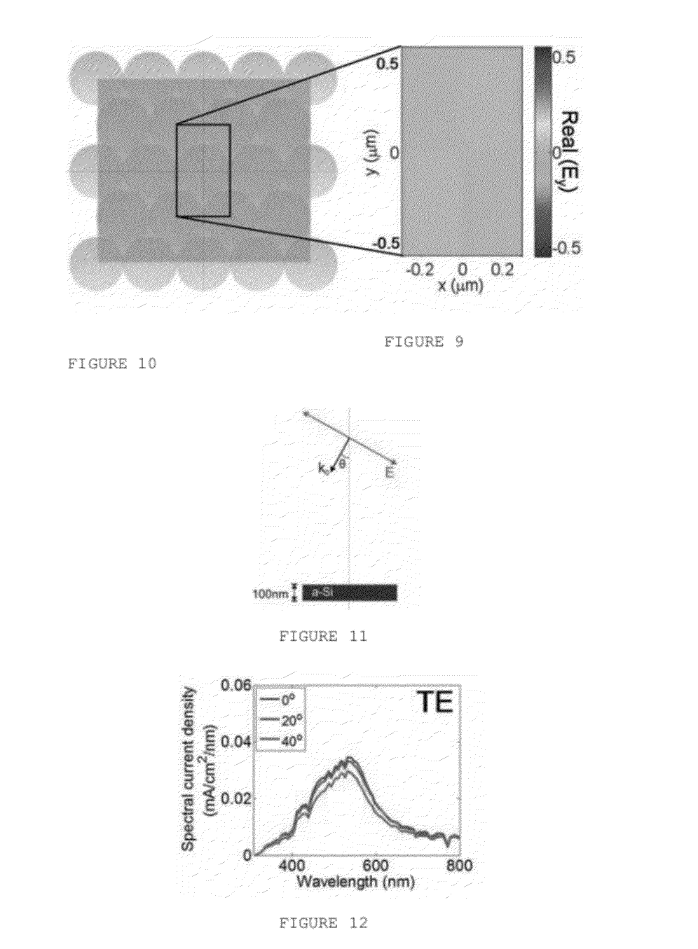

FIG. 6-7 represent the E_{y} component of the electric field for a cross section in the (x,y)-plane in the middle of the a-Si layer. The observed field profile is periodic and oscillates in phase with the period. Because the sphere array by itself has very low loss, the mode energy eventually gets absorbed into the a-Si and increases the generated photocurrent. In FIG. 7, the E_{y} component of the electric field is shown, corresponding to a transverse electric (TE) guided mode along the x-axis. There also exists a transverse magnetic (TM) guided mode of the same periodicity that contributes to the enhancement of the absorption at λ=665 nm. As a comparison, FIG. 8-9 show an equivalent analysis, off resonance at λ=747 nm. There is no resonance in the sphere and no excitation of a guided mode at this wavelength.

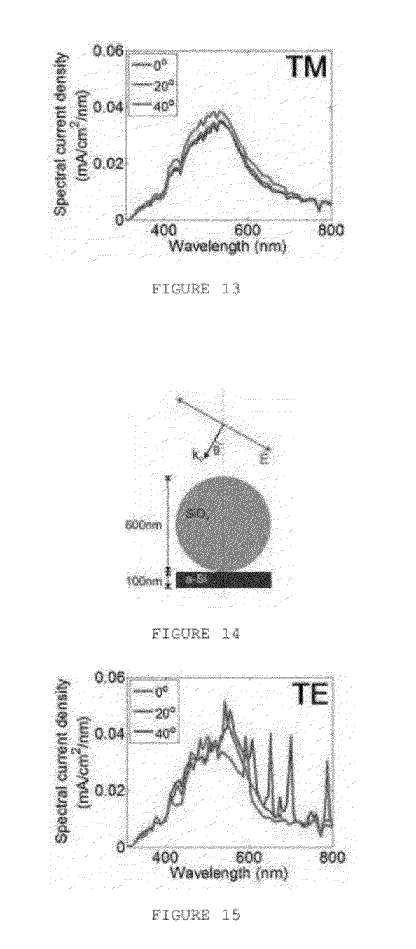

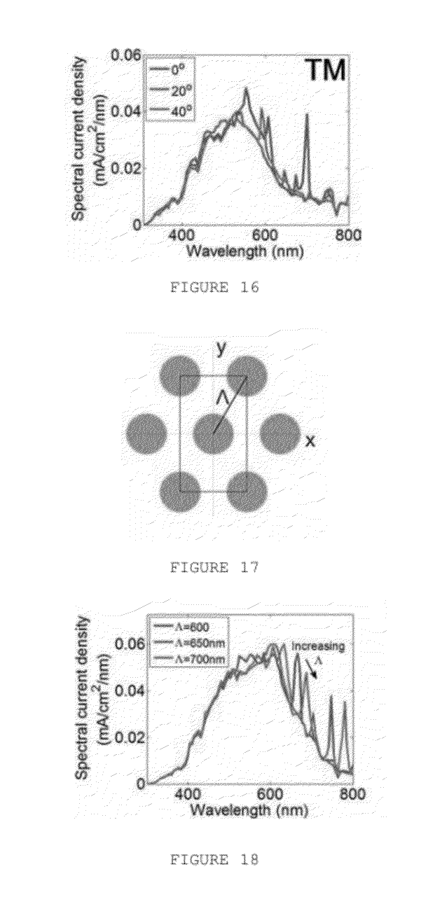

The spherical shape of the structure above the solar cell also enables incoupling at large angles of incidence. In order to verify this, the absorbed light at normal incidence and at 20° and 40° angle to the normal were compared in both TE and TM polarizations. For simplicity, only an array of silica spheres above a 100-nm a-Si layer were considered. FIGS. 11 and 14 show a schematic of the simulated structures without and with silica spheres on top of the a-Si. FIGS. 12 and 13 and 15-16 correspond to the spectral current density in the a-Si for both cases without and with silica spheres, respectively, and for TE and TM polarizations. For normal incidence, the calculated improvement is 29.6% and is independent of the polarization. This high improvement compared to the prior solar cell can be explained by the absence of an antireflection coating layer and back reflector layer in this simplified case. For TM polarization, the improvement is 13.8% for 20° and 3.9% for 40° incidence angle. For TE polarization, the improvement compared to a flat layer remains around 29% for all angles. However, in the case of a flat a-Si film with incident TM polarization, the larger the angle, the larger the energy absorbed. That is why the current improvement of a structure with spheres decreases over that of a structure without spheres in the case of a TM polarized incident plane wave.

As the lattice constant Λ of the hexagonal array of spheres varies, as represented in FIG. 17, the absorption due to the WGM-guided wave changes due to different coupling conditions between the spheres. In FIG. 18, the spectral current density for different spacings between the spheres is shown. The peak at λ=665 nm for close-packed spheres is shifted to longer wavelengths as the distance between the spheres increases. This provides evidence that the incoupling is due to a diffractive mechanism. For Λ=650 nm and Λ=700 nm, a second peak appears at λ=747 nm and λ=780 nm, respectively. This corresponds to an optimal coupling condition between the WGM and the a-Si waveguide mode for these specific periodicities and wavelengths. For the considered design, a separation of Λ=700 nm gives the highest current density with J=14.14 mA cm⁻², which represents an enhancement of 15% compared to a flat a-Si cell with an antireflection coating. As shown in FIG. 19, when Λ>1000 nm, the coupling between the spheres almost disappears and the enhancement significantly decreases. From an experimental point-of-view, the spacing between spheres could be varied by an additional coating on each sphere or by assembly on photolithographically patterned substrates. Thus, changing the spacing between the spheres allows one to tune and adjust which wavelengths are coupled into the solar cell.

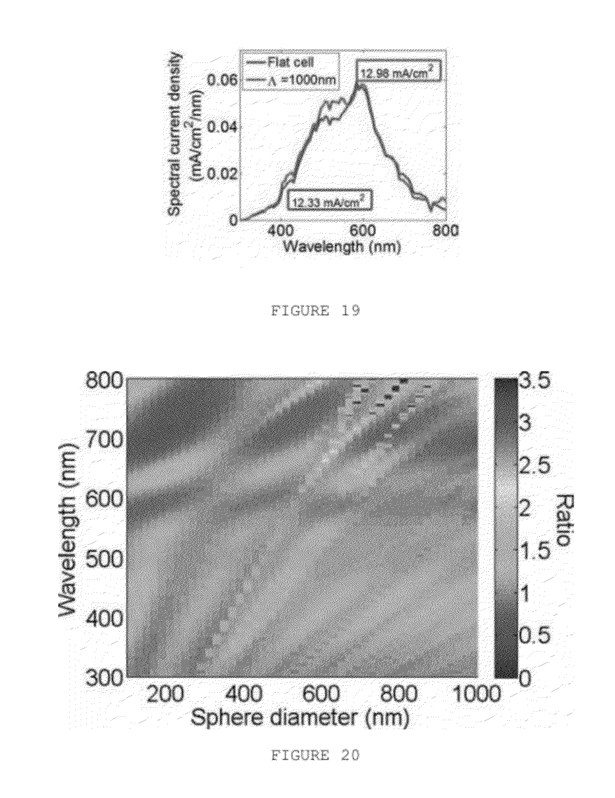

In order to estimate the influence of the sphere diameter on the enhancement of the solar cell efficiency, FIG. 20 illustrates the ratio between the spectral current density of a solar cell with hexagonally close-packed spheres over the spectral current density of a solar cell without spheres. The sphere diameter varies between D=100 nm and D=1000 nm. A general broadened enhancement was observed due to the effective textured antireflection coating created by the layer of spheres. Moreover, strong enhancement occurs in corresponding to optical dispersion of the array of coupled whispering gallery mode dielectric spheres. Note that the effective dispersion curves in FIG. 20 appear as arrays of bright dots; this is a plotting artifact arising from simulation at discrete sphere diameters spaced in increments of 20 nm. Because the a-Si absorption becomes weaker above λ=600 nm, the enhancement corresponding to the WGMs becomes significant above this wavelength. This strong enhancement where a-Si is weakly absorbing is obtained for sphere diameters between 500 and 900 nm. Therefore, a way to broadly enhance the a-Si absorption in this weakly absorbing region could be to randomly mix sphere diameters in the range 500 to 900 nm.

The disclosure demonstrates several photovoltaic absorber configurations based on a periodic array of resonant silica nanospheres atop an a-Si layer and demonstrated that strong whispering gallery modes can significantly increase light absorption in a-Si thin-film solar cells. The disclosure provides a solar cell where a resonant guided mode is excited due to a nanosphere array above the active layer and is eventually absorbed in the a-Si under it. The spectral position of the absorption enhancement can be easily tuned by varying the sphere diameter and lattice constant. Also, the number of resonances can potentially be increased to make the response more broadband by assembling arrays of spheres with different diameters. This concept has advantages over other absorption enhancement schemes because the in-coupling elements are loss-less and their spherical geometry allows light to be efficiently coupled into the solar cell over a large range of incidence angles. Also these arrays can be fabricated and easily scaled using standard self-assembly techniques without the need for lithography. In addition to this, the presented enhancement results are performed on a flat a-Si layer, which has an advantage over cells grown on textured surfaces as surface roughness or topography can create holes or oxidation and thus reduce the efficiency and lifetime of the solar cell. The sphere array can also be easily integrated or combined with existing absorption enhancement techniques. This light trapping concept offers great flexibility and tenability and can be extended for use with many other thin-film solar cell materials.

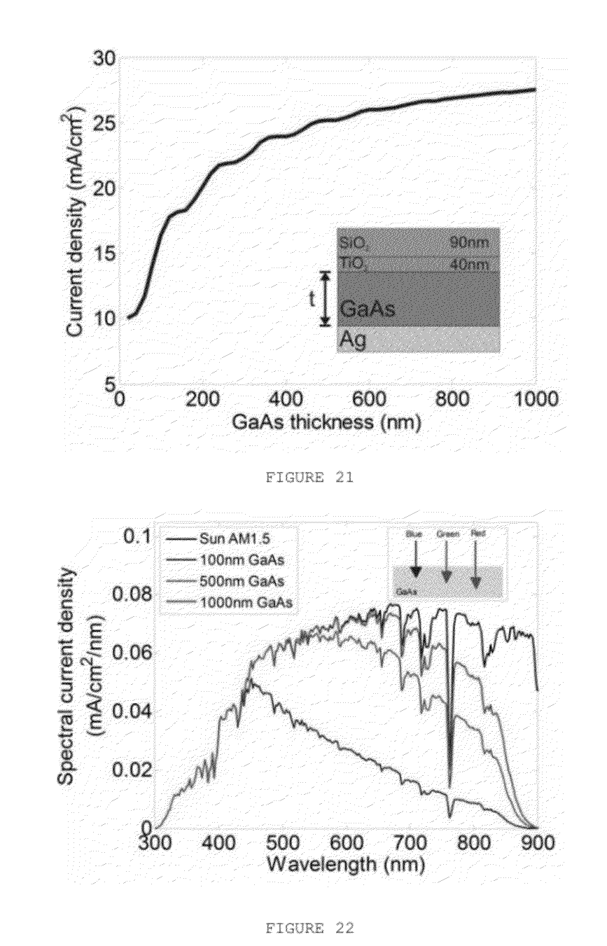

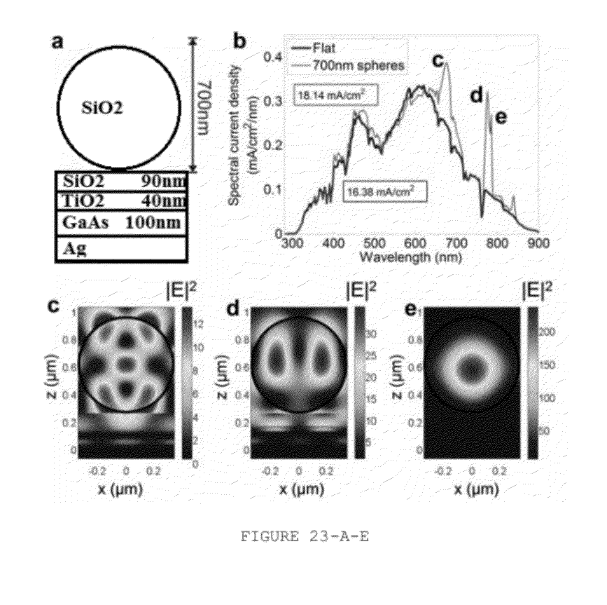

Experiments were also performed using other PV cell materials (e.g., GaAs). A GaAs solar cell with a 40 nm thick titanium dioxide (TiO₂) and 90 nm thick SiO₂ double layer antireflection coating and a silver back reflector was analyzed. A broadband wave pulse with the electric field polarized along the x-axis is injected at normal incidence on the structure, and the fields are monitored at 300 wavelengths equally spaced between λ=300 nm and λ=900 nm. This wavelength range corresponds to the sun's energy spectrum below the bandgap of GaAs. The optical generation rate in the GaAs is calculated using:

$${G}_{opt}^{n} ( ω ) = \int \frac{{ɛ}^{″} ( ω ) {\vert E ( ω ) \vert}_{GaAs}^{2}}{2 ℏ} {Γ}_{solar} ( ω ) d V \qquad ( 2 )$$

where |E(ω)|_{GaAs}² is the electric field intensity integrated over the GaAs volume and ∈″(ω) is the imaginary part of the dielectric function of the GaAs. Γₛₒₗₐᵣ(ω) is a factor used to weight each wavelength by the AM1.5 solar spectrum. We represent in FIG. 21 the current density of a flat GaAs solar cell with back reflector and double anti-reflection coating as a function of the GaAs thickness. The current density considerably increases within the first five hundred nanometers. This shows that most of the light is absorbed within this range. For a 500 nm thick GaAs solar cell, we calculate a current spectral density of 25.19 mA/cm². Then, above 500 nm, the current density slowly increases to reach 27.56 mA/cm² for a 1000 nm thick GaAs solar cell. This value corresponds to 82% of the maximum attainable value. Even though this value is high, it still gives potential for improvement.

FIG. 22 shows the AM1.5 solar spectrum and plots that indicate the fraction of the solar energy absorbed in three thin GaAs layers on a single pass. The current density is calculated by J=Gₐₙₐⁿ(ω)e⁻ where e⁻ is the elementary charge and

Gₐₙₐⁿ(ω)=α(ω)N₀∫e^{-α(ω)x}dx (3)

is the analytically calculated optical generation rate. N₀ is the sun photon flux at the top of the GaAs layer and α(ω)=4π\sqrt{∈″(ω)}/λ the absorption coefficient. FIG. 22 gives an indication of where in the spectral range there exists potential for improvement to increase the absorption in a GaAs absorbing layer for the three considered thicknesses. As depicted a large fraction of the solar spectrum is poorly absorbed, especially in the 600-900 nm spectral range for the case of a 1 μm thick GaAs absorbing layer. Thus, a way to increase the absorption in this particular wavelength range will have a direct influence on the solar cell's efficiency.

In order to estimate the influence of a hexagonally close-packed monolayer array of dielectric nanospheres atop the flat GaAs solar cell (FIG. 1b), 3D full field finite difference time domain (FDTD) electromagnetic simulations were performed to determine the expected absorption enhancement. A schematic of the cross section is represented in FIG. 23a. In FIG. 23b, the expected spectral current density in the case of a flat GaAs solar cell were compared with a cell with a hexagonally close-packed monolayer array of 700 nm dielectric nanospheres for a 100 nm thick GaAs solar cell. Several peaks corresponding to different whispering gallery mode orders in the nanospheres were labeled above the solar cell. For the case represented in FIG. 23d, the enhancement due to the sphere's whispering gallery mode is more than 300%. Because in the near infrared part of the solar spectrum GaAs is weakly absorbing, in this case, due to the monolayer spheres array, the generated current density can be enhanced by more than 11%.

In FIG. 24a, b, c, the ratio between the spectral current density of a solar cell with hexagonally close packed spheres are illustrated over the spectral current density of a solar cell without spheres for three different thicknesses of GaAs: 100 nm, 500 nm and 1000 nm, respectively. The spheres' diameter vary between D=100 nm and D=900 nm. Strong enhancement occurs corresponding to optical dispersion of the array of coupled whispering gallery mode dielectric spheres. In FIG. 24d, e, f, the current densities are plotted as a function of the sphere's diameter for the same GaAs thicknesses previously described. In the case of the 100 nm thick GaAs solar cell, the highest current density is obtained for 700 nm diameter spheres and equals J=18.14 mA/cm² (see FIG. 24d). In the case of a flat GaAs solar cell, the same current density would be obtained for a 160 nm thick GaAs solar cell, which means that in this particular case, it is possible to save 37.5% of the active material to obtain the same amount of current density. In FIG. 24a, the enhancement due to the WGM appears in the range between 700 nm and 900 nm wavelength where the enhancement lines directly refer to the WGM orders. In the case of the 500 nm thick GaAs solar cell, the highest current density is obtained with 500 nm diameter hexagonally close packed nanospheres on top of it and equals J=26.00 mA/cm². This corresponds to a 3.2% enhancement compared to a flat GaAs solar cell with double antireflexion coating where the current density equals J=25.19 mA/cm². Note that, as shown in FIG. 24e, in order to obtain the same current density with a flat GaAs solar cell, one would have needed 600 nm of active material. For the case of the 1000 nm thick GaAs solar cell, the highest current is obtained for D=500 nm diameter spheres and is equal to J=27.41 mA/cm² (see FIG. 24f). Some enhancement for subwavelength diameter spheres is also seen, probably due to scattering effects. Further modifications to optimize the thickness and diameters can be performed. The absorbed currents can potentially be increased further by utilizing spheres of multiple diameters, partially embedding the spheres or texturing the underlying AR coatings. Slightly tuning the spacing between the spheres to a=20 nm, the current reaches J=28.23 mA/cm² which corresponds to an enhancement of 2.5% compared to a flat solar cell with double antireflection coating. The enhancement occurs mainly at wavelength scale diameter spheres where low order whispering gallery modes occur. In the case of 740 nm diameter nanospheres, tuning the spacing to a=120 nm between the spheres increases the spectral current from J=27.90 mA/cm² for a hexagonally close packed array of nanospheres to J=28.13 mA/cm². This represents an enhancement of 2.0% compared to a flat solar cell with double antireflection coating. While this enhancement is less than shown earlier for the case of the 500 nm diameter sphere array with 20 nm spacing, a part of the enhancement occurs near the band edge, which may be beneficial for thin cells. Analysis suggests that this separation results in a greater coupling between the array of spheres and the active material. This is most likely due to a better coupling between the spheres themselves as the field profile suggests.

A number of embodiments of the invention have been described. Nevertheless, it will be understood that various modifications may be made without departing from the spirit and scope of the invention. Accordingly, other embodiments are within the scope of the following claims.

What is claimed is:

1. An electrical energy generating device, comprising:
a photovoltaic cell;
a plurality of nanostructures layered adjacent to a surface of the photovoltaic cell, wherein the nanostructures undergo resonance when contacted with incident light and wherein light passes through the nanostructures before entering the photovoltaic cell.

2. The device of claim 1, wherein the surface is a side of an anti-reflective coating included on the photovoltaic cell and the nanoparticles each physically and directly contacts the surface.

3. The device of claim 3, wherein the anti-reflective coating is electrically conductive.

4. The device of claim 1, wherein the nanostructures are each constructed of a dielectric material.

5. The device of claim 4, wherein the nanostructures each includes SiO₂.

6. The device of claim 1, wherein each nanostructure is a nanosphere.

7. The device of claim 6, wherein each nanosphere has a diameter and the diameter of each nanosphere is the same.

8. The device of claim 6, wherein each nanosphere has a diameter in a range of 1 nm to 2500 nm.

9. The device of claim 6, wherein each nanosphere has a diameter in a range of 100 nm to 900 nm.

10. The device of claim 6, wherein each nanosphere has a diameter and the diameters are heterogeneous.

11. The device of claim 1, wherein the nanoparticles are arranged in a one nanostructure thick monolayer.

12. The device of claim 1, wherein the nanostructures are configured such that whispering gallery modes of light having a wavelength in a range UV to long infrared wavelengths resonate within the nanostructures.

13. The device of claim 1, wherein the nanostructures are configured such that whispering gallery modes of light at about 350-700 nm wavelength resonate within the nanostructures.

14. The device of claim 11, wherein the nanostructures are nanospheres.

15. The device of claim 1, wherein the nanostructures are arranged in a repeating pattern.

16. The device of claim 1, wherein the nanostructures are arranged in a periodic pattern.

17. The device of claim 1, wherein the nanostructures are spaced from one another by about 10-200 nm.

18. The device of claim 1, wherein the nanostructures each physically and directly contacts each of the nearest nanostructures.

19. The device of claim 18, wherein the nanostructures are arranged in a two dimensional lattice.

20. The device of claim 19, wherein the nanostructures are arranged in a close packed hexagonal structure.

21. The device of claim 1, wherein the photovoltaic cell comprises a light absorbing semiconductive material.

22. The device of claim 21, wherein the light-absorbing semiconductive material includes at least one dopant selected from a group consisting of a p-type dopant and an n-type dopant.

23. The device of claim 21, wherein the semiconductive material is selected from a group consisting of amorphous silicon, germanium, indium gallium phosphide, and gallium III arsenide.

24. The device of claim 1, wherein the photovoltaic cell comprises a layer of a light-absorbing semiconductive material and the layer has a thickness in a range of 10 to 1000 nm.

25. An electrical energy generating device, comprising:
a solar cell having a surface through which light enters and a light-absorbing medium that absorbs the light that enters the solar cell, the solar cell being configured to convert the absorbed light to electrical energy; and
nanostructures immobilized relative to the surface such that the light passes through the nanostructures before entering the solar cell, each nanoparticle being a nanosphere and each nanosphere having a diameter in a range of 1 nm to 2500 nm, the nanostructures being arranged in a one nanostructures thick monolayer such that the nanostructures are in a lattice configuration, and the nanostructures being configured such that whispering gallery modes of light having a wavelength in a range of 380 nm to 780 nm resonate within the nanoparticles.

26. A device comprising a resonant lossless dielectric layer applied to a solar cell absorber layer.

27. The device of claim 26, wherein the resonant lossless dielectric layer comprises a layer of nanostructures.

28. The device of claim 26, wherein the absorber layer comprises a semiconductive material.

29. The device of claim 26, wherein the resonant lossless dielectric layer and the absorber layer are separated by an electrode.
